(19) United States
(12) Patent Application Publication
(10) Pub. No.: US 2016/0052068 A1
(43) Pub. Date: Feb. 25, 2016

(54) Method for Producing a Drill Hole and a Drilling Machine for this Purpose

(71) Applicant: Skybrain Vermogensverwaltungs GmbH, Rodermark (DE)

(72) Inventors: Markus Winterschladen, Kahl (DE); Jochem Berkmann, Eppertshausen (DE)

(21) Appl. No.: 14/826,827

(22) Filed: Aug. 14, 2015

(30) Foreign Application Priority Data
Aug. 19, 2014 (EP) 14181459.0

(51) Int. Cl. B23B 41/02; H05K 3/00

(52) U.S. Cl. CPC B23B 41/02; H05K 3/0047; B23B 2228/41; B23B 2228/36; B23B 2270/32; B23B 2270/48

(57) ABSTRACT

The invention relates to a method for producing drill holes (12, 13a, 13b) in a sandwich component (6). The sandwich component has several interconnected layers of which at least one layer (9) is electrically conducting and the directly adjacent layers (10) are not electrically conducting. Further, the invention relates to a drilling machine (1) having at least one drill (5), a measuring device that is connected to the drill (5) that measures a difference in potential between a component (6) and a reference potential, a depth measuring device that can measure the position of the drill (5) relative to a reference point, and a computer unit that is equipped to execute the method automatically.

The invention relates to a method for producing a drill hole or a deep drill hole in a sandwich component that can have several, sometimes interconnected layers. One or several of these layers can be electrically conducting, while the directly adjacent layers, for example, are not electrically conducting. Further, the invention relates to a drilling machine that is equipped to execute such a method.

In some technical areas, drill holes must be placed into sandwich components that must reach a defined depth. Frequently, it is not the absolute depth of the drill hole that is relevant, rather, it is a relative depth having a reference plane in the interior of the material. Thus, it can be required to drill through a certain electrically conducting layer, for example, regardless of its position within the sandwich component, and avoid contact with the subsequent electrically conducting layer with the drilling tool.

Together with other electrically conducting layers, the electrically conducting layer should either have a capacitor effect or be guided outward in such a way that it can be contacted (provided with earth). Examples of sandwich components of this type are multilayered printed circuit boards or sandwich systems with an aluminum/ceramic structure.

The exact finishing of sandwich components of this type is sometimes made more difficult thereby, that the precise position of the individual layers within the component is not known exactly. Thus, during the production of sandwich components when the individual layers are pressed, deviations in the thickness of the individual layers and their alignment within the sandwich component can be occur.

When drill holes are to be inserted into such a sandwich component in which a certain position is drilled through at a certain distance, for example, while the adjacent layer is not intended to be drilled through any more, these types of fluctuations in the positioning of the layers within the sandwich component can have the effect that a certain layer is not reached by mistake, or is unintentionally drilled through. This can lead to the uselessness of the entire sandwich component.

For this reason, DE 43 40 249 A1 describes a device in which a drilling machine has a conducting drill (drilling tool) and the individual layers of a sandwich component and the drill are connected to a measuring device so that a difference in potential between the individual layers can be determined by the drill as soon as it reaches the electrically conducting layer. Beyond that, a height measuring unit is provided for the drill by means of which the height of the drill can be measured relative to the surface of the workpiece. The basic principle of this approach is reliable for several application purposes, in particular, when the number of the electrically conducting layers present, and their approximate position within the sandwich component is known. However, it is a disadvantage of this system that the drill simultaneously contacts several electrically conducting layers depending on the drilling depth, which generally leads to imprecise measurements. Beyond that, it is difficult to take possible error signals into consideration.

It is therefore the objective of the present invention to propose improved methods for the production of drill holes or deep drill holes and a drilling machine for such.

This problem is solved by the method as recited in claim 1, 10 or 12 and by a drilling machine as recited in claim 15.

The method as recited in claim 1 relates to the production of a drill hole in a sandwich component that has several interconnected layers, of which at least one layer is electrically conducting and the two directly adjacent layers are not electrically conducting. (In other words, a dielectric medium as nonconducting layer is located between several conducting layers, for example.) Thereby, upon commencing the method, the exact position of the at least one electrically conducting layer within the sandwich component is unknown. However, the sequence of the layers within the sandwich component is generally known. In other words, it is possible, for example, when the component has three electrically conducting layers—subsequent to determining the first electrically conducting layer—to identify the next electrically conducting contact as the second layer. According to the invention, the method includes the following steps:

a) First, a drilling machine is provided that either has several spindles with different drills (drilling tools) and/or whose drills can be interchanged. Thereby, the drills used for the method according to the invention are electrically conducting and while they are in use, they are connected with a measuring device that measures a difference in potential between the at least one electrically conducting layer and a reference potential, for example, earth (ground). Beyond that, a depth measuring unit is provided by means of which the position of the drill relative to a reference point, for example, the surface of the sandwich component or the position of the drill in which it is pulled back to its maximum, can be measured. Advantageously, this depth measuring unit is connected with the advance of the drill or the Z axis measuring system (Thus, when a contact is established, the depth is known directly/immediately. The depths are then tapped by the individual measuring systems of the stations).
b) In a first processing step, a drill hole is first inserted into the sandwich with the drilling machine until the drill (or its tip) is in a position in which—in the direction of drilling—the upstream, not electrically conducting layer adjacent to the electrically conducting layer is presumed to be located. In other words, in the first processing step, a drill hole is inserted into the sandwich component in which, based on previous knowledge about the structure of the sandwich component it is to be expected that it is still located at a distance to the electrically conducting layer. Thereby, if several electrically conducting layers are already being drilled through, the depth measuring system records the positions (depths) of the various layers. By using this method it is generally possible to identify a number of layers in a single drilling stroke. The quality of the signals generated depends on the geometric structural conditions (diameter and edge angle of the drill, the thickness of the electrical layer, the distance of the electrical layers to each other). If the distance of the electrical layers is too small, for example, the measuring system may detect several layers as being one continuous layer.
c) For this reason, in order to increase the precision of capture, the drill can subsequently be drawn back out of the blind hole that was created and exchanged with an additional drill having a smaller diameter. This can occur either by means of a tool change or by using an additional drill spindle that has a drill with a smaller diameter. At least while it is being used, this smaller drill is in turn connected with the measuring device for measuring the difference in potential.
d) The additional drill with the smaller diameter can then be inserted into the blind hole that was created previously with the drill having the larger diameter and with the additional drill, a drill hole can be inserted into the sandwich component, at least until the measuring device detects an electrically conducting layer.

Hereby, the position of the additional drill relative to the reference point is determined by means of the depth measuring unit

By using the smaller drill, any contact between the inner wall of the previously drilled bond hole and the smaller drill is avoided, so that the measuring device does not come in contact with conducting or nonconducting layers. The first contact of the smaller drill that is detected by the measuring device is therefore most certainly the sought-after electrically conducting layer. This method distinguishes itself thereby, that erroneous signals can be avoided or at least significantly reduced, and even possible malfunctions due to short circuits of several electrically conducting layers above the drill can be precluded.

e) Optionally, after detecting the sought-after electrically conducting layer, a through drill hole is produced in the sandwich component by either continuing to drill with the additional (smaller) drill in the blind hole or with another tool change or spindle change so that the through drill hole can be made with the first (larger) drill, for example. It does not need to be connected with the measuring device or be electrically conducting in the event the through drill hole is to be produced exclusively. Preferably, the electrically conducting layers can be recorded even during this drilling process.

Generally, it is possible in the case of several electrically conducting layers within a component, that at least a few or each one of these electrically conducting layers are captured in sequence in their position individually by using the aforementioned method. When the signal quality is suitable, it is also possible to record several electrical layers during one drilling process at a good level of quality. Only after several or all layers have been captured sequentially relative to their position, a through drill hole will then be produced, if appropriate.

In other words, steps h) and c) and d) are performed optionally for each electrically conducting layer individually, in particular then, when the precision of the deep drill hole is intended to be maximized.

When recording the positions (depths) by the depth measuring unit in step b), in the strict sense, the absolute Z values of the individual stations are recorded. In order to have a clean zero level or reference level, preferably, the respective laser switching point is used when dimensioning the tool. If that is not done, the reference can be lost after a tool change if the tools, for example, project differently out of the spindle respectively. The quality of the depth precision also depends on the quality of the laser measurement.

The optional steps c) and d) are for the purpose of improving the signal quality. According to experience it is possible to capture two, sometimes also three or more layers in one drill passage (one shot). The more electrical layers are drilled through in a drilling process, the worse the signal. In other words, the dispersion of the signal increases exponentially with each additionally detected layer in the drill passage. But for the invention this also means that in principle, the layers can also be recorded in “one shot”. Steps b) and c) are thus performed optionally in order to improve the quality of the depth.

In the following, a sandwich component means, in particular, a plate-shaped component having a length and width (dimension in the XY direction) that is generally significantly larger than its thickness (z direction). Even the individual layers of the sandwich component essentially extend in the XY plane at a low height in the Z direction. Thereby, the drilling typically takes place perpendicular to the XY plane, i.e. in the Z direction. Generally, the thickness of nonconducting layers is greater than that of the electrically conducting layers that can be thin films, for example. Generally, the nonconducting layers are prepregs or also adhesives or resin.

According to a preferred embodiment, the at least one electrically conducting layer is connected with the measuring device. This can be accomplished, for example, by means of a contact area at one of the lateral edges of the sandwich component. Alternatively or additionally, for measuring the difference in potential by the measuring device, the capacitor effect can be used when several electrically conducting layers are provided. The measuring device is then equipped to measure a difference in potential that is generated by the capacitor effect between the reference potential, for example, earth, and the potential of the electrically conducting layers.

According to a preferred embodiment of the method according to the invention, if the optional through drill hole in step e) is not produced with the additional (smaller) drill, the through drill hole can be produced with a drill having an outer diameter that is larger than that of the additional (smaller) drill. In this way it is possible that even in step e) of the method according to the invention, the position of the drill relative to the reference point is once again determined by means of the depth measuring unit when the measuring device once again detects reaching the electrically conducting layer subsequent to the position detected in step b). Hereby, it is possible to once again review the value measured in step d), as a result of which the precision of the method is increased further. In particular, if the position of some or all electrically conducting layers was determined previously already, the through drill hole can be inserted without the drill having to stop at each electrically conducting layer.

According to a particularly preferred embodiment of the invention, in a sandwich component having several electrically conducting layers—in step b) of the method—the drill stops at each contact detected by the measuring device. The electrically conducting layer is then not completely drilled through but the drill has, at the most, provided a small recess in the electrically conducting layer. In order to clean up the drill hole and the contact surface toward the electrically conducting layer, the drill can pause at this position for a short time; subsequently it is pulled out of the drill hole entirely or partially. As the result of renewed further drilling, once again a contact is detected by the measuring device at the electrically conducting layer. If upon renewed further drilling all contacts detected by the measuring device are ignored up to reaching the position at which the drill has stopped last, the position of the electrically conducting layer can be determined very precisely and error-free. In other words, in this embodiment, the position of an electrically conducting layer is determined at least twice in succession. The thus determined values can be compared and/or tested for plausibility.

The method can be performed in a particularly advantageous manner by using a drill as described in the still unpublished German patent application 10 2013 004 679. With the exception of the tip, this drill is provided with a nonconducting coating or only the tip and the drill are electrically conducting, so that possible contacts at the inner wall of the drill hole cannot be detected by the measuring device. The use of such a drill thus increases the precision of the method.

The precision of the method according to the invention can also be further increased by inserting several drill holes that are offset with respect to each other, or through drill holes in the sandwich component, whereby the aforementioned steps are performed at least for several drill holes. In this way, the electrically conducting layer that was detected at a position can be tested.

To improve the precision of the method even further, the positions of the drill relative to the reference point as determined by the depth measuring unit can be tested for plausibility and if necessary, corrected mathematically. This can be done by a stochastic analysis, for example, a frequency distribution and/or by filtering certain values. Hereby, it can be taken into consideration that although the position of a layer within the sandwich component can vary slightly and/or deviate from an ideal value, no erratic distortions occur.

When inserting a through drill hole with a small diameter compared to the thickness of the sandwich component, generally, the drill is on a run. In this case, in order to create through drill holes, the sandwich components are drilled from both sides, respectively up to one half (so-called flip drilling). When inserting the drill hole from the front and from the back, the method according to the invention can also be used. The deep drill hole(s) of the front side of the sandwich component is thereby produced in such a way that the Z axis stops within one of the middle layers. When inserting the drill hole on the back, this layer is now drilled anew from its rear side. As the thickness of the individual layers is known at a good level of quality, the data determined by both drilling processes can now be offset in order to also capture deep reference layers. Thereby, the two drilling processes can be “one shot” respectively or optionally complemented by steps b) and/or c) to increase the precision.

In most application cases, for example, in printed circuit boards, when several electrically conducting layers are present, their number is known. In this way it is possible to determine the position of the drill relative to the reference point by means of the depth measuring unit always then, when the measuring device detects that an electrically conducting layer has been reached. In conjunction with the knowledge of the number of electrically conducting layers, the search for a certain electrically conducting layer can be facilitated in this way, or the precision of the determination of the position can be improved. A particularly preferred application of the aforementioned method is the production of several through drill holes in a sandwich component, whereby this process is used for determining the precise position of one or several electrically conducting layers within the sandwich component that is needed for subsequent processing steps. After they have been provided with a number of through drill holes, some sandwich components are subjected to a treatment in which a thin sleeve or layer consisting of an electrically conducting material is deposited on the inner side of the drill hole. In order to realize circuitry in a sandwich component, for example, these sleeves or deposits must be drilled in a defined manner so that the sleeve or deposit remains within the drill hole only in defined zones. This takes place by means of so-called deep drill holes in which a drill ingresses the drill hole only up to a certain position and thereby removes the sleeve or coating and stops in such an exact manner that in other areas, the sleeve or the coating continue to remain in a defined manner. In this way, a targeted interconnection of several electrically conducting layers in a sandwich component is possible.

A self-contained inventive concept relates, independent of the previously described steps, to a method for the production of a deep drill hole in a sandwich component that has several interconnected layers of which at least one layer is electrically conducting and the directly adjacent layers are not electrically conducting. Thereby, the exact position of the electrically conducting layer within the sandwich component is initially unknown. For this reason, producing a deep drill hole in which an exact position within the sandwich component is to be reached, for example, by just reaching an electrically conducting layer but not drilling through it, is not possible with an adequate degree of precision. For this, the method according to the invention provides that first the position of at least one electrically conducting layer is determined within the sandwich component at several positions that are at a distance to each other. In the subsequent step, a virtual three-dimensional model of the sandwich component including its layers, at least the at least one electrically conducting layer is generated from this position data. Based on this three-dimensional model, the deep drill hole is then produced. Thereby, it is not required to first capture the exact position of an electrically conducting layer within the sandwich component individually at each position at which a deep drill hole is to be inserted. Rather, it is sufficient that the three-dimensional model determines a calculated position value of the electrically conducting layer for each position at which a deep drill hole is to be inserted.

Thereby, to prepare the virtual three-dimensional model of the sandwich component, in addition to the measured position data of the electrically conducting layers within the sandwich component, information about the number and distribution of the individual layers within the sandwich component can be used. Further, filters or mathematical methods can be used in order to test the plausibility of the measured positions of an electrically conducting layer within the component. In this way, faulty measurements or highly improbable measuring positions can be ignored when generating the three-dimensional model. Determining the position of the at least one electrically conducting layer within the sandwich component at several positions that are at a distance to each other can be accomplished in various ways. Thus it is possible, for example, to use the previously described methods during the insertion of through drill holes. Alternatively or additionally, the position data can be generated as it is also described in the as yet unpublished German patent application 10 2013 004 679.

Producing a deep drill hole in which an exact drilling depth is to be reached within a sandwich component is associated with difficulties in practice even when the position of the drilling depth to be reached within the sandwich component is known, because most of the time, the sandwich components lie on a carrier for finishing upon which in turn lies a backup layer on which the sandwich component is positioned, onto which in turn one or several cover layers (entry) are applied. As a result of slight imperfections in flatness within this structure, faults can occur when the deep drill hole is inserted even when the layer structure within the sandwich component is known precisely.

A further core idea of the present invention addresses this problem independent of the previously cited steps. For this, it is provided according to the invention, that at least a lower layer is placed on a table of a drilling machine, thereafter, the sandwich component is placed onto the lower layer and subsequently, at least one upper layer is placed onto the sandwich component. Subsequently, the distance of at least one reference point on the upper layer relative to the surface of the table is measured. From this, the depth of the deep drill hole relative to the reference point on the upper layer is calculated and the deep drill hole is inserted into the sandwich component up to this calculated depth.

The distance measurement is preferably accomplished thereby, that the upper layer is electrically conducting and upon lowering the drill onto the upper layer, a contact is detected, whereby simultaneously, by means of a different measuring unit, the height of the drill bit above the surface of the table is measured. For this method it is required to know at least the thickness of the upper layer that is to be expected so that it can be taken into consideration when calculating the depth of the deep drill hole.

According to an especially preferred embodiment of the invention, the distance is measured not only at one reference point between the upper layer and the surface of the table, but a number of reference points are measured. In this way, the topography of the stack lying on the table of the drilling machine consisting of lower layer, sandwich component and upper layer can be calculated that can be taken into consideration for determining the depth of the deep drill hole. Preferably, such a measurement is made at each position at which a deep drill hole is to be provided. When calculating the depth of the deep drill hole, even the aspect ratio between the measured distance between the reference point on the upper layer and the surface layer of the table can be taken into consideration in addition to known nominal values of the thicknesses of the individual layers.

A further refinement of this method provides that initially, prior to the application of the sandwich component, only the at least one lower layer and the at least one upper layer are placed on top of each other on the table of the drilling machine. Subsequently, at least one reference point is measured on the upper side of the upper layer as described above. Preferably, once again the distance of several reference points on the upper layer is measured relative to the surface of the table. Subsequently, the sandwich component is positioned between the lower layer and the upper layer and once again the distance between at least one reference point on the upper layer is measured relative to the surface of the table. The depth of the deep drill hole relative to the reference point on the upper layer can then be calculated by using the measured results before and after the insertion of the sandwich component.

A refinement of the inventive idea provides that the sandwich component is first with the—during drilling upper side—inserted aligned downward between the at least one lower layer and the at least one upper layer, and the measurement is performed as described above. Subsequently, the sandwich component is turned around into the correct position so that the—during drilling upper side—points upward. Then, the distances can be measured once more. By using these values, the depth of the deep drill hole relative to a reference point on the upper layer can then be calculated.

For this method it is required to know the depth of the deep drill hole relative to the surface of the sandwich component with sufficient precision. This can be determined by using one of the other methods according to the inventing as described above.

A further aspect of the invention relates to a drilling machine having at least one drill, a measuring device connected with the drill that measures a difference in potential above the drill between a component, for example, a layer of a sandwich component and a reference potential, a depth measuring unit by means of which the position of the drill can be measured relative to a reference point, and with a computer unit that is equipped to execute one of the aforementioned methods. The computer unit can, for example, also perform the aforementioned calculations by means of stored or input datasets, as well as by taking the measured values of the measuring device and/or the depth measuring unit into consideration.

In the following, the invention is described in further detail by also referring to the enclosed drawing. Schematically shown are:

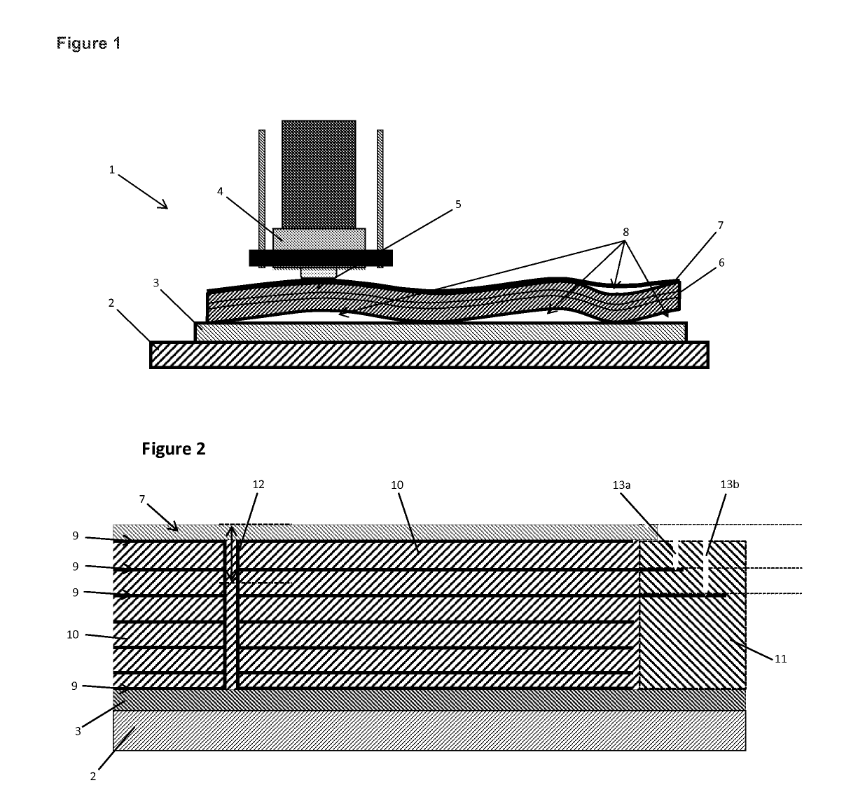

FIG. 1 shows a lateral view of a drilling machine according to the invention with a sandwich structure (in cross section) having highly enlarged irregularities;

FIG. 2 shows the layer structure in cross section while a sandwich component is being finished;

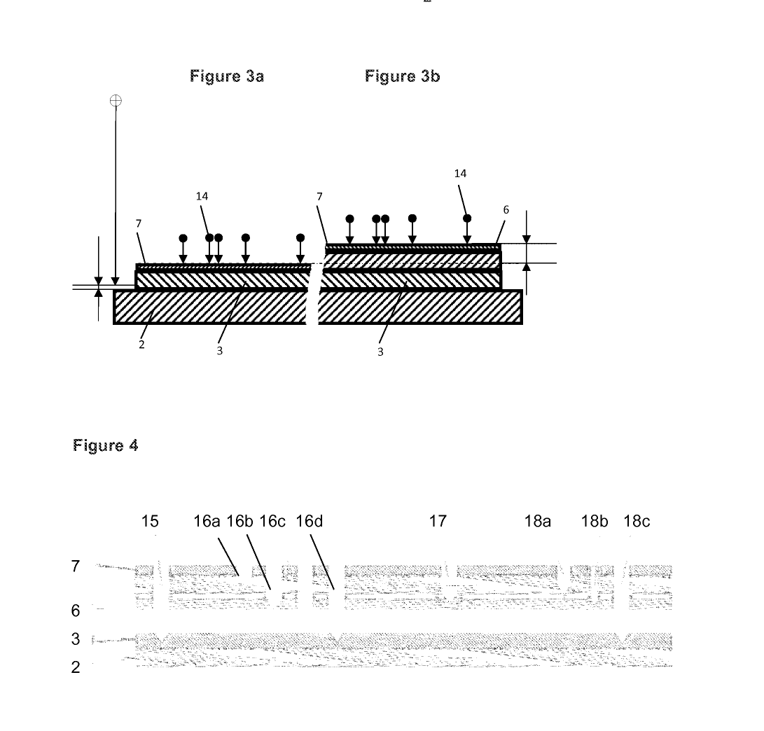

FIGS. 3a, 3b shows two simplified method steps for the preparation of deep drill holes, and

FIG. 4 shows a cross section of various ways of finishing a sandwich component.

FIG. 1 shows a drilling machine 1 that has a level table 2 and a backup layer 3 that is provided on it. Further, drilling machine 1 has at least one drilling spindle 4 with a drilling tool 5. A sandwich component 6 is placed on backup layer 3, which is exaggeratedly wavy in the illustration in FIG. 1. Generally, sandwich component 6 is an essentially plate-shaped component that has slight imperfections in flatness of sometimes several tenth of a millimeter depending on the thickness of the plate. In turn, a cover layer (entry) 7 lies on sandwich component 6. Different than in the illustration in FIG. 1, between table 2 and backup layer 3, a carrier or the like can be provided, for example. Further, it is possible, that the cover layer is designed multilayered, for example, having an electrically conducting uppermost layer. In the illustration shown in FIG. 1, the width of the component is the X direction, for example, and the thickness of the component the Z direction.

As can be seen in the enlarged illustration in FIG. 2, sandwich component 6 is constructed of several layers that can be pressed together or glued together, for example. In the illustrated embodiment, sandwich component 6 has a number of electrically conducting layers 9 as well as layers 10 provided between such that are not electrically conducting and thus insulate layers 9 from each other. In FIG. 2 on the right side, a contact area 11 is indicated that can, for example, be an edge section of sandwich component 6. In FIG. 2, reference number 12 indicates a through drill hole that extends through all layers of sandwich component 6. Further, in contact area 1, two blind holes 13a, 13b are formed that can serve to connect individual electrically conducting layers 9 with a measuring device of drilling machine 1. Blind hole 13a thereby extends from the surface of sandwich component 6 up to the level of the second electrically conducting layer while blind hole 13b extends up to the third electrically conducting layer.

In FIGS. 3a and 3b, two preparatory method steps for the production of deep drill holes are indicated. For this, according to FIG. 3a, first backup layer 3 is placed on the table and directly on top of it, cover layer 7. With this layer structure, the tip of the drill measures—as indicated by the arrows—the height of this layer structure above the surface of table 2 at various reference points 14 on the surface of cover layer 7, for example, at positions at which deep drill holes are to be inserted next. In a subsequent step of the method, according to FIG. 3b, sandwich component 6 is placed between backup layer 3 and cover layer 7. Thereupon, the distance to the upper side of table 2 is once again measured with the tip of the drill at reference points 14 on the upper side of cover layer 7. Based on a comparison of the measured values obtained according to FIGS. 3a and 3b, for each reference point 14 that corresponds, for example, to the location of a deep drill hole to be inserted, at a known thickness of the cover layer and at a known position of the electrically conducting layers within sandwich component 6, a deep drill hole can be inserted in such a way that the drill can be slopped in a defined manner shortly before or shortly after one of the electrically conducting layers 9.

FIG. 4 shows various types of finishing a sandwich component in cross section. Shown are the drilling, pulse drilling (peck drilling), the boundary of the system drilling/pulse drilling and the method according to the invention by using several drills with various diameters.

In the schematically illustrated sandwich component 6 in FIG. 4, between cover layer (entry) 7 and backup layer 3, two hatched, thicker, non-conducting layers and two conducting layers (black lines) are provided separated by a thin dielectric medium (white).

In FIG. 4 on the left, a drill hole labelled 15 is inserted that has, for example, the desired nominal diameter. As described above, the drilling tool (not shown) can determine the position of the electrically conducting layer within the sandwich component while the drill hole is being inserted upon detecting an electrical contact between the drilling tool and the electrically conducting layer.

Instead of a single drilling process, to determine the position of one or several layers in component 6, a method described as pulse drilling or peck drilling can also be used in which several drill holes 16a, 16b, 16c and 16d of differing depths are inserted into the component.

However, different than in the illustration in FIG. 4, drill holes 16a, 16b, 16c and 16d are inserted at the same position instead of being offset, i.e. the drilling tool ingresses several times in sequence at the same position of component 6 at increasingly lower depth. In order to simplify the explanation of the method, the drill holes are shown offset. Thereby, with a suitable process control (stop within an electrically conducting layer), the contacts already captured previously can be verified upon each ingression.

Drill hole 17 in FIG. 4 shows the technical limits of the precision of determining the position during drilling or peck drilling. The quality of the signals generated depends on the geometric structural conditions such as the diameter and the edge angle of the drilling tool, the thickness of the electrical layer and the distance of the electrical layers to each other. If the distance of the electrical layers is too small, for example, the measuring system may detect several layers as one continuous layer. This is the case in drill hole 17 in FIG. 4, as the tip of the drilling tool is simultaneously contacting both electrically conducting layers, thereby short-circuiting them.

A method in which the positions of electrically conducting layers in component 6 can be determined with a high degree of precision is indicated by drill holes 18a, 18b and 18c. First, drill hole 18a is produced with a first (larger in diameter) drilling tool. As soon as the tip of the drilling tool comes in contact with the upper electrically conducting layer in FIG. 4, the advance of the drilling tool stops. The drilling tool is then pulled back from blind hole 18a and exchanged with another drilling tool that has a smaller diameter. With this (smaller) drilling tool, the same drill hole is again drilled, whereby the wall of the previously produced drill hole 18a does not come in contact with the drilling tool Thereby, previous contacts or other interference factors can be eliminated and the first contact of the (smaller) drilling tool is then the conducting layer. Reference number 18b shows the blind hole produced by the (smaller) drilling tool that is shown next to (actually at the same location) drill hole 18a solely for reasons of clarity. 18c identifies a through drill hole that is produced, for example, again with the first (larger) drilling tool subsequent to verifying the position of the electrically conducting layers with the second (smaller) drilling tool. Even upon inserting drill hole 18c, which is in turn shown offset to drill holes 18a and 18b for the sole reason of clarity, the position of the electrically conducting layers can once again be verified.

### REFERENCE NUMBERS

1 drilling machine
2 table
3 backup layer/lower layer (backup)
4 drill spindle
5 drill (tool)
6 sandwich component
7 cover layer/upper layer (entry)
8 trapped air
9 electrically conducting layer
10 not electrically conducting layer
11 contact area
12 through drill hole
13a, b blind hole
14 reference point
15 drill hole
16a-d drill hole
17 drill hole
18a-c drill hole

1-15. (canceled)

16. A method for producing a drill hole in a sandwich component having several interconnected layers of which at least one layer is electrically conducting and the directly adjacent layers are not electrically conducting, wherein the exact position of the electrically conducting layer within the sandwich component is unknown, comprising the following steps:
a) Providing a drilling machine, having a drill that is electrically conducting, a measuring device connected with the drill that measures a difference in potential between the at least one electrically conducting layer and a reference potential by means of the drill and a depth measuring unit by means of which the position of the drill can be measured relative to a reference point;
b) Inserting a drill hole into the sandwich component with the drilling machine up to the presumed position in the direction of drilling of the upstream, not electrically conducting layer adjacent to the electrically conducting layer;
c) Optionally, pulling back the drill and exchanging it with an additional drill having a smaller exterior diameter, whereby the smaller drill is in turn connected with the measuring device;
d) Optionally, inserting the additional drill into the blind hole produced in step b) and inserting a drill hole with the additional drill at least until the measuring device detects that an electrically conducting layer has been reached and determining the position of the additional drill relative to the reference point by means of the depth measuring unit;
e) Where applicable, producing a through drill hole in the blind hole produced in step d).

17. The method as recited in claim 16, wherein the at least one electrically conducting layer is connected with the measuring device.

18. The method as recited in claim 16, wherein several electrically conducting layers are provided, whereby the measuring device is equipped to measure a difference in potential generated by a capacitor effect between the reference potential and the potential of the electrically conducting layer.

19. The method as recited in claim 16, wherein in step e) the trough drill hole is produced with the additional drill.

20. The method as recited in claim 16, wherein in step e) the trough drill hole is produced with a drill that has an exterior diameter that is larger than that of the additional drill.

21. The method as recited in claim 20, wherein in step e) the position of the drill is determined relative to the reference point by the depth measuring unit when the measuring device detects that an electrically conducting layer has been reached subsequent to the position reached in step b).

22. The method as recited in claim 16, wherein several electrically conducting layers are provided, whereby in step b) the drill stops upon each contact detected by the measuring device, thereupon, is pulled back out of the drill hole entirely or partially, and subsequently, drilling resumes, whereby up to reaching the position at which the drill stopped last, contacts detected by the measuring device are ignored.

23. The method as recited in claim 16, wherein several electrically conducting layers are provided, the number of which is known, whereby the position of the drill is determined relative to the reference point by the depth measuring unit at any time the measuring device detects that an electrically conducting layer has been reached.

24. The method as recited in claim 16, wherein the position of the drill relative to the reference point that has been determined in step d) and/or according to claim 21 by the depth measuring unit is tested for plausibility and if necessary, a corrected position is calculated for the electrically conducting layer.

25. A method to produce a deep drill hole in a sandwich component that has several interconnected layers of which at least one layer is electrically conducting and the directly adjacent layers are not electrically conducting, whereby the exact position of the electrically conducting layer within the sandwich component is unknown, comprising the following steps:
i) Determining the position of the at least one electrically conducting layer within the sandwich component at several positions that are at a distance to each other;
ii) Generating a virtual three-dimensional model of the sandwich component including at least one of its layers based on the results of step i),
iii) Inserting the deep drill hole based on the model generated in step ii).

26. The method as recited in claim 25, wherein the position is determined according to a method as recited in claim 16.

27. The method for producing a deep drill hole in a sandwich component, whereby the depth of the deep drill hole relative to a surface of the sandwich component is known, comprising the following steps:
Placing at least one lower layer on a table of a drilling machine,
placing the sandwich component onto the lower layer,
placing at least one upper layer onto the sandwich component,
measuring the distance of at least one reference point on the upper layer relative to the surface of the table,
calculating the depth of the deep drill hole relative to the reference point on the upper layer and
inserting the deep drill hole up to the calculated depth.

28. The method as recited in claim 27, wherein prior to the placement of the sandwich component, the at least one lower layer and the at least one upper layer are placed on top of each other on the table, thereafter, the distance of at least one reference point on the upper layer is measured relative to the surface of the table, thereafter, the sandwich component is inserted between the lower layer and the upper layer and once again the distance between at least one reference point (14) on the upper layer is measured relative to the surface of the table, whereby the depth of the deep drill hole relative to the reference point on the upper layer is calculated by taking the measured results before and after inserting the sandwich component into consideration.

29. The method as recited in claim 27, wherein the depth of the deep drill hole relative to a surface of the sandwich component is determined beforehand by means of a method as recited in claim 1 through 11.

30. A drilling machine having at least one drill, a measuring device that is connected with the drill that measures a difference in potential between a component and a reference potential by means of drill, a depth measuring unit by means of which the position of the drill can be measured relative to a reference point, and a computer unit that is equipped to automatically execute a method as recited in claim 16.
